(19) United States
(12) Patent Application Publication
(10) Pub. No.: US 2024/0274597 A1
(43) Pub. Date: Aug. 15, 2024

(54) MOS-BASED DESIGN SOLUTIONS FOR SOLVING WELL-PID

(71) Applicant: Taiwan Semiconductor Manufacturing Company, Ltd., Hsinchu (TW)

(72) Inventors: Chia-Lin HSU, Hsinchu (TW); Yu-Ti Su, Hsinchu (TW)

(21) Appl. No.: 18/320,724

(22) Filed: May 19, 2023

Related U.S. Application Data
(60) Provisional application No. 63/484,242, filed on Feb. 10, 2023.

(51) Int. Cl. H01L 27/02; H01L 21/8249; H01L 29/08

(52) U.S. Cl. CPC H01L 27/0292; H01L 21/8249; H01L 27/0274; H01L 29/0847; H01L 27/0207

(57) ABSTRACT

A circuit includes a substrate, p-well regions over the substrate and including n- channel metal-oxide semiconductor field-effect transistors, n-well regions over the substrate and including p-channel metal-oxide semiconductor field-effect transistors, drain/source regions of protection metal-oxide semiconductor field-effect transistors, and at least one control circuit. First conductive connections connect selected drain/source regions to the p-well regions and the n-well regions, second conductive connections connect selected n-channel metal-oxide semiconductor field-effect transistors and p-channel metal-oxide semiconductor field-effect transistors to one another, and third conductive connections are configured to connect gates of the protection metal-oxide semiconductor field-effect transistors to the at least one control circuit.

### CROSS-REFERENCE TO RELATED APPLICATIONS

This application claims priority from U.S. Provisional Patent Application No. 63/484,242 filed on Feb. 10, 2023, which is hereby incorporated in its entirety.

### BACKGROUND

Plasma processing plays a vital role in semiconductor manufacturing. Plasma is used in processes such as plasma enhanced chemical vapor deposition (PECVD), plasma etching including plasma dry etching, and plasma cleaning. Plasma induced damage (PID) is a critical issue in designing metal-oxide semiconductor field-effect transistors (MOSFETs), since PID may increase circuit degradation and variability.

PID is a reliability issue that crosses all process generations. Process rules have been established to avoid some PID risks, such as metal-PID risks. However, well-PID has become an issue at several process nodes and in some designs, such as process nodes and designs that include wells with different well sizes. Various devices have been proposed as solutions for well-PID, but it is difficult to implement device-level solutions for well-PID where no solution meets all direct current (DC), electrostatic discharge (ESD), and/or PID situations.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the disclosure and are not intended to be limiting.

FIG. 1 is a diagram schematically illustrating a semiconductor device and three different options that can be used to reduce or eliminate well-PID, in accordance with some embodiments.

FIG. 2 is a diagram schematically illustrating a well-PID protection circuit as first option well-PID protection (shown in FIG. 1), in accordance with some embodiments.

FIG. 3 is a diagram schematically illustrating the well-PID protection circuit of FIG. 2 with the control circuit electrically connected to the gate of the MOSFET by a conductive path, in accordance with some embodiments.

FIG. 4 is a diagram schematically illustrating well-PID protection circuits in various voltage applications, in accordance with some embodiments.

FIG. 5 is a diagram schematically illustrating the semiconductor device including the well-PID protection circuits as first option well-PID protection, in accordance with some embodiments.

FIG. 6 is a cross-section diagram of the semiconductor device of FIG. 5, in accordance with some embodiments.

FIG. 7 is a diagram schematically illustrating the semiconductor device including the local well-PID protection circuits as third option well-PID protection, in accordance with some embodiments.

FIG. 8 is a cross-section diagram of the semiconductor device of FIG. 7, in accordance with some embodiments.

FIG. 9 is a method of fabricating a semiconductor device, in accordance with some embodiments.

FIG. 10 is a block diagram schematically illustrating an example of a computer system configured to provide the semiconductor devices and methods of the current disclosure, in accordance with some embodiments.

FIG. 11 is a block diagram of a semiconductor device manufacturing system and a semiconductor device manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure relates to circuits and methods for protecting semiconductor devices, such as integrated circuits, from PID, such as well-PID, in metal-oxide semiconductor (MOS) circuits. The well-PID may be related to n-wells and/or p-wells in the semiconductor device.

Disclosed embodiments include a MOS-based design solution for well-PID that includes a control circuit configured to be connected to a gate of a MOSFET. The MOSFET includes a drain/source region connected to a well region. During manufacturing, the gate of the MOSFET floats such that accumulated charge in the well region discharges through the MOSFET. In operation of the device, the control circuit is connected to the gate of the MOSFET to bias off the MOSFET and prevent current from flowing through the MOSFET.

Advantages and benefits of the disclosed embodiments include low or small impact on area, little or no impact on functionality, no ESD concerns, suitable for all designs with different voltage applications, and suitable for every technology node, including advanced finFET and planar processes.

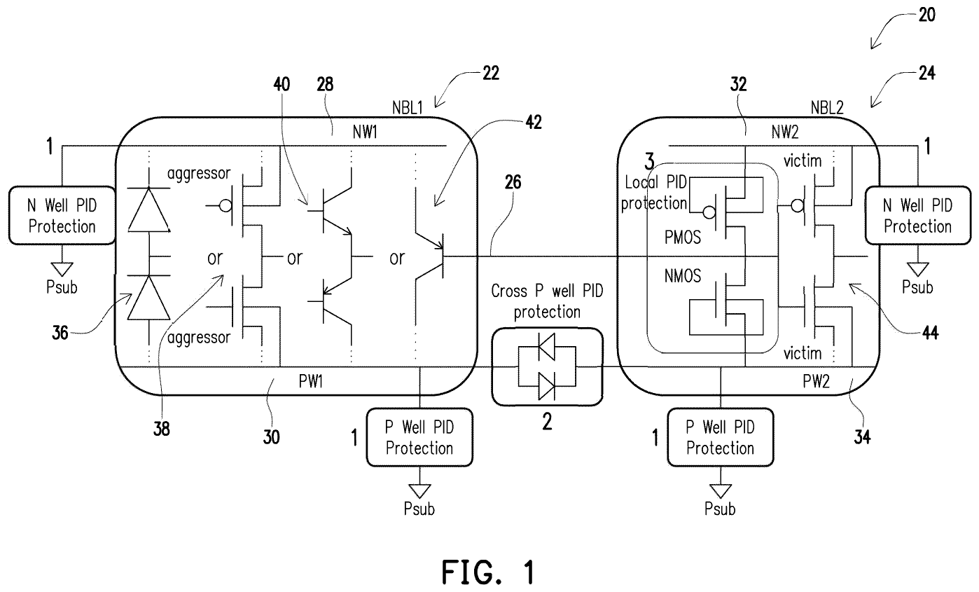

FIG. 1 is a diagram schematically illustrating a semiconductor device 20 and three different options, labeled as “1”, “2”, and “3” that can be used to reduce or eliminate well-PID, in accordance with some embodiments. The semiconductor device 20 includes a first n-buried layer NBL1 22 and a second n-buried layer NBL2 24. The first n-buried layer NBL1 22 is electrically connected to the second n-buried layer NBL2 24 by a conductive path 26. In some embodiments, the semiconductor device 20 includes a first deep n-well instead of the first n-buried layer NBL1 22. In some embodiments, the semiconductor device 20 includes a second deep n-well instead of the second n-buried layer NBL2 24.

The first n-buried layer NBL1 22 includes a first n-well region NW1 28 and a first p-well region PW1 30, and the second n-buried layer NBL2 24 includes a second n-well region NW2 32 and a second p-well region PW2 34. Each of the first n-well region NW1 28 and the first p-well region PW1 30 is larger than each of the second n-well region NW2 32 and the second p-well region PW2 34.

Well-PID occurs during the fabrication process, where negative or positive plasma induced charges accumulate in the well regions, such as in the first n-well region NW1 28, the first p-well region PW1 30, the second n-well region NW2 32, and the second p-well region PW2 34. The larger well regions in the first n-buried layer NBL1 22 accumulate more plasma induced charge than the smaller well regions in the second n-buried layer NBL2 24. The accumulated charge differences can result in large voltage differences across gate oxides in the second n-buried layer NBL2 24, where the gate oxides in the second n-buried layer NBL2 24 are connected to junctions in the first n-buried layer NBL1 22 by conductive paths, such as the conductive path 26. The voltage of each of the well regions is related to the charge accumulated in the well region, which depends on the number of vias (or via count) and the n-buried layer NBL area. Thus, the gate oxides in the second n-buried layer NBL2 24 may encounter large voltage stresses that result in non-optimal or inoperable devices in the second n-buried layer NBL2 24, which is known as well-PID.

In FIG. 1, the first n-buried layer NBL1 22 includes a junction situated between the first n-well region NW1 28 and the first p-well region PW1 30. The larger first n-buried layer NBL1 22 with the junction is referred to as an aggressor. The junction in the first n-buried layer NBL1 22 can be any suitable device such as a pair of diodes 36, a p-channel metal-oxide semiconductor field-effect transistor (MOSFET) and an n-channel MOSFET 38, an NPN bipolar junction transistor (BJT) and a PNP BJT 40, and/or a single BJT 42.

The second n-buried layer NBL2 24 includes a gate oxide situated between the second n-well region NW2 32 and the second p-well region PW2 34. The smaller second n-buried layer NBL2 24 that includes the gate oxide is referred to as the victim. The gate oxide in the second n-buried layer NBL2 24 can be one or more of the gates of a p-channel MOSFET and an n-channel MOSFET 44, with the gates connected to each other and to the junction in the first n-buried layer NBL1 22 by the conductive path 26.

The junction in the first n-buried layer NBL1 22 is electrically connected to the gate oxide in the second n-buried layer NBL2 24 by the conductive path 26, such that charge can flow between the junction in the first n-buried layer NBL1 22 and the gate oxide in the second n-buried layer NBL2 24 to cause well-PID.

The first option, labeled as “1”, can be used to reduce or eliminate well-PID. Well-PID protection can be provided from the first n-well region NW1 28 to a p-substrate 46, from the first p-well region PW1 30 to the p-substrate 46, from the second n-well region NW2 32 to the p-substrate 46, and/or from the second p-well region PW2 34 to the p-substrate 46. In some embodiments, the first well-PID protection option 1 includes using a reverse biased diode connected between the target well region and the p-substrate, where charge accumulated in the well region is discharged through the diode in the reverse biased state.

The second option, labeled as “2”, includes cross p-well PID protection that extends between the first p-well region PW1 30 and the second p-well region PW2 34. In some embodiments, the second well-PID protection option 2 includes a first diode extending in one direction between the first p-well region PW1 30 and the second p-well region PW2 34 and a second diode extending in the other direction between the second p-well region PW2 34 and the first p-well region PW1 30.

The third option, labeled as “3”, provides local well-PID protection from the gate oxide to the second n-well region NW2 32 and from the gate oxide to the second p-well region PW2. In some embodiments, the third well-PID protection option 3 includes a first p-channel MOSFET extending between the gate oxide and the second n-well region NW2 32 and a first n-channel MOSFET extending between the gate oxide and the second p-well region PW2 34, where the gates of the first p-channel MOSFET and the first n-channel MOSFET are floating.

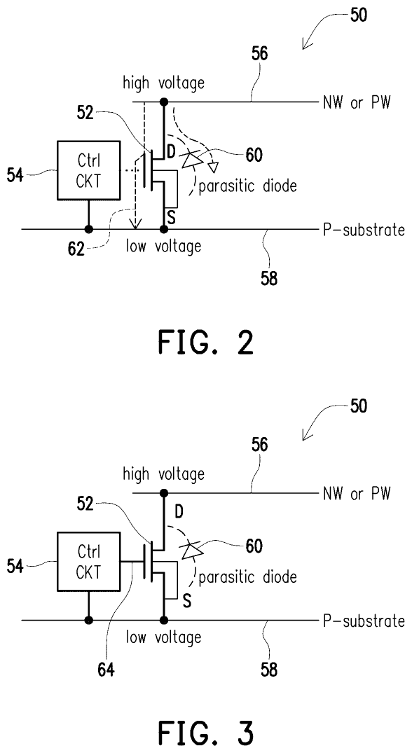

FIG. 2 is a diagram schematically illustrating a well-PID protection circuit 50 as first option 1 well-PID protection (shown in FIG. 1), in accordance with some embodiments. The well-PID protection circuit 50 includes a MOSFET 52 and a control circuit 54. The MOSFET 52 is an n-channel MOSFET. The control circuit 54 is configured to be connected to the gate of the MOSFET 52, but in the example shown in FIG. 2 is not yet connected to the gate. In some embodiments, the control circuit 54 is part of a larger circuit on the semiconductor device 20. In some embodiments, the control circuit 54 is a separate circuit on the semiconductor device 20. In some embodiments, the control circuit 54 includes one or more invertors (INVs), NOR gates, NAND gates, and/or other circuits. In other embodiments, the MOSFET is a p-channel MOSFET.

The drain region D of the MOSFET 52 is connected to a well 56 and the source region S of the MOSFET 52 is connected to bulk silicon, such as p-substrate 58. Also, each of the body of the MOSFET 52 and the control circuit 54 is connected to the bulk silicon. The well 56 can be an n-well or a p-well. The well-PID protection circuit 50 is used to reduce or eliminate well-PID.

The gate of the MOSFET 52 remains floating during most if not all the fabrication process, such that the MOSFET 52 is not biased completely off during the fabrication process. When voltage at the well 56 is higher than voltage at the p-substrate 58, charge accumulated in the well 56 is discharged through a reverse biased parasitic diode 60 of the MOSFET 52 and through an extra leakage path 62 from the drain to the source of the MOSFET 52. The gate remains floating during the fabrication process to create this extra leakage path 62 and discharge charge that accumulates in the well 56.

FIG. 3 is a diagram schematically illustrating the well-PID protection circuit 50 of FIG. 2 with the control circuit 54 electrically connected to the gate of the MOSFET 52 by a conductive path 64, in accordance with some embodiments. The conductive path 64 includes metal connections in the semiconductor device 20, such as metal layers and vias. In some embodiments, the conductive path 64 is manufactured at or toward the end of the fabrication process. In some embodiments, the conductive path 64 is manufactured after completing the fabrication process.

The control circuit 54 biases off the MOSFET 52 during operation of the semiconductor device 20 to prevent leakage current through the MOSFET 52. For example, the n-channel MOSFET 52 is biased off by grounding the gate of the MOSFET 52.

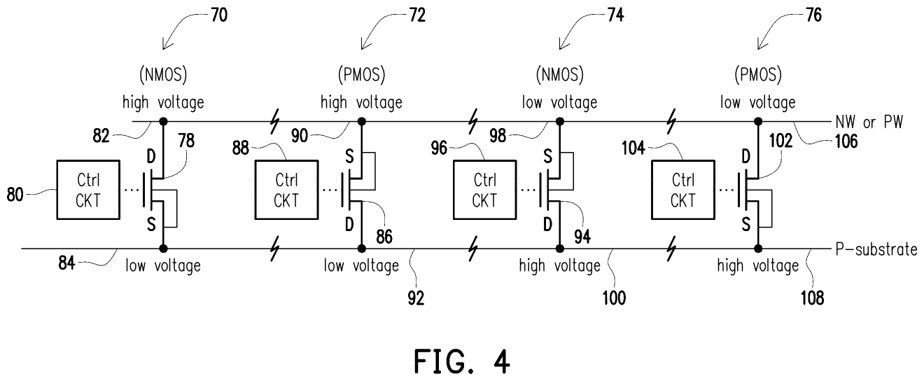

FIG. 4 is a diagram schematically illustrating well-PID protection circuits 70, 72, 74, and 76 in various voltage applications, in accordance with some embodiments. The well-PID protection circuits 70, 72, 74, and 76 are used to reduce or eliminate well-PID.

The well-PID protection circuit 70 includes an n-channel MOSFET (NMOS transistor) 78 and a control circuit 80 that is configured to be connected to the gate of the NMOS transistor 78. The drain region D of the NMOS transistor 78 is connected to a well 82 and the source region S of the NMOS transistor 78 is connected to p-substrate 84. Also, the body of the NMOS transistor 78 is connected to the p-substrate 84. The well 82 can be an n-well or a p-well.

During fabrication, the gate of the NMOS transistor 78 is floating such that if the voltage of the well 82 is greater than the voltage of the p-substrate 84, the NMOS transistor 78 discharges charge accumulated in the well 82 through the parasitic diode of the NMOS transistor 78 and, with the gate floating, through the extra leakage path of the NMOS transistor 78.

The well-PID protection circuit 72 includes a p-channel MOSFET (PMOS transistor) 86 and a control circuit 88 that is configured to be connected to the gate of the PMOS transistor 86. The source region S of the PMOS transistor 86 is connected to a well 90 and the body of the PMOS transistor 86 is connected to the well 90. The drain region D of the PMOS transistor 86 is connected to p-substrate 92. The well 90 can be an n-well or a p-well.

During fabrication, the gate of the PMOS transistor 86 is floating such that if the voltage of the well 90 is greater than the voltage of the p-substrate 92, the PMOS transistor 86 discharges charge accumulated in the well 90 through the parasitic diode of the PMOS transistor 86 and, with the gate floating, through the extra leakage path of the PMOS transistor 86.

The well-PID protection circuit 74 includes an NMOS transistor 94 and a control circuit 96 that is configured to be connected to the gate of the NMOS transistor 94. The source region S of the NMOS transistor 94 is connected to a well 98 and the body of the NMOS transistor 94 is connected to the well 98. The drain region D of the NMOS transistor 94 is connected to p-substrate 100. The well 98 can be an n-well or a p-well.

During fabrication, the gate of the NMOS transistor 94 is floating such that if the voltage of the well 98 is less than the voltage of the p-substrate 100, the NMOS transistor 94 discharges charge accumulated in the p-substrate 100 through the parasitic diode of the NMOS transistor 94 and, with the gate floating, through the extra leakage path of the NMOS transistor 94.

The well-PID protection circuit 76 includes a PMOS transistor 102 and a control circuit 104 that is configured to be connected to the gate of the PMOS transistor 102. The drain region D of the PMOS transistor 102 is connected to a well 106 and the source region S of the PMOS transistor 102 is connected to p-substrate 108. Also, the body of the PMOS transistor 102 is connected to the p-substrate 108. The well 106 can be an n-well or a p-well.

During fabrication, the gate of the PMOS transistor 102 is floating such that if the voltage of the well 106 is less than the voltage of the p-substrate 108, the PMOS transistor 102 discharges charge accumulated in the p-substrate 108 through the parasitic diode of the PMOS transistor 102 and, with the gate floating, through the extra leakage path of the PMOS transistor 102.

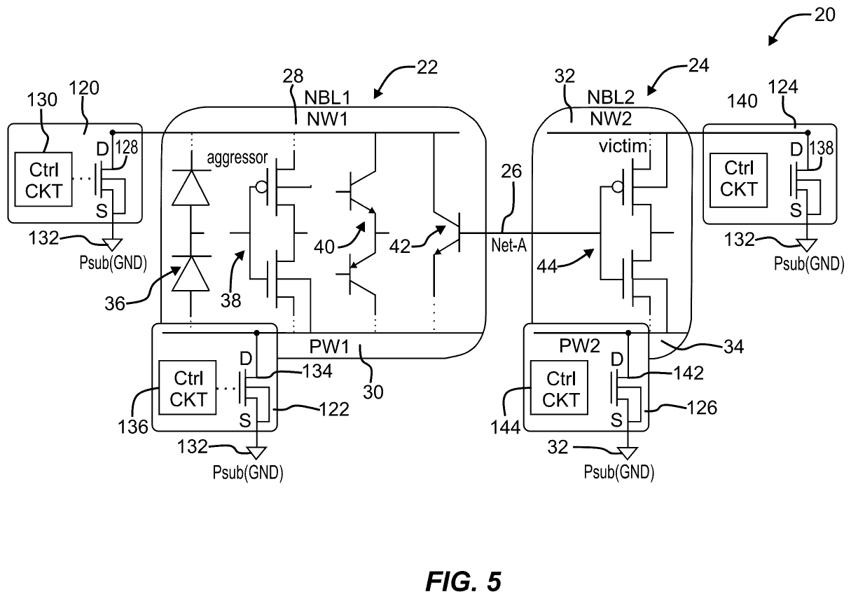

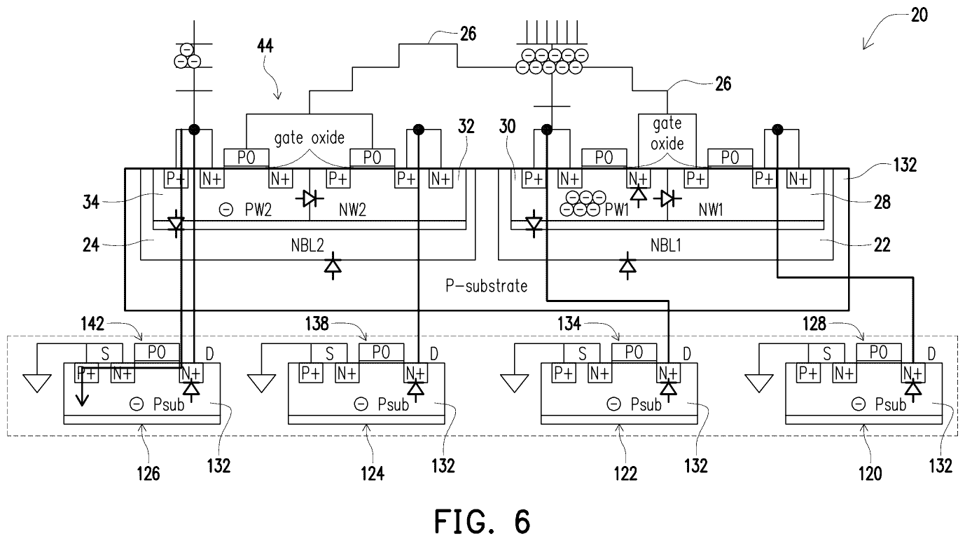

FIGS. 5 and 6 are diagrams schematically illustrating the semiconductor device 20 of FIG. 1 including well-PID protection circuits 120, 122, 124, and 126, in accordance with some embodiments. The well-PID protection circuits 120, 122, 124, and 126 are first option 1 well-PID protection (shown in FIG. 1), such as the well-PID protection circuit 50 of FIGS. 2 and 3. Each of the well-PID protection circuits 120, 122, 124, and 126 includes a MOSFET and a control circuit. In embodiments, the MOSFET can be an NMOS transistor or a PMOS transistor based on the voltage applications of the well-PID protection circuits 120, 122, 124, and 126, such as the voltage applications described in relation to well-PID protection circuits 70, 72, 74, and 76 of FIG. 4.

FIG. 5 is a diagram schematically illustrating the semiconductor device 20 including the well-PID protection circuits 120, 122, 124, and 126 as first option 1 well-PID protection, in accordance with some embodiments. FIG. 6 is a cross-section diagram of the semiconductor device 20 of FIG. 5, in accordance with some embodiments.

In reference to FIGS. 5 and 6, the semiconductor device 20 includes the first n-buried layer NBL1 22 and the second n-buried layer NBL2 24. The first n-buried layer NBL1 22 is electrically connected to the second n-buried layer NBL2 24 by the conductive path 26. The first n-buried layer NBL1 22 includes the first n-well region NW1 28 and the first p-well region PW1 30, and the second n-buried layer NBL2 24 includes the second n-well region NW2 32 and the second p-well region PW2 34. Each of the first n-well region NW1 28 and the first p-well region PW1 30 is larger than each of the second n-well region NW2 32 and the second p-well region PW2 34.

The first n-buried layer NBL1 22 includes one or more junctions in the first n-well region NW1 28 and the first p-well region PW1 30. The larger first n-buried layer NBL1 22 with the junctions is referred to as the aggressor. The junctions can be in any suitable device such as a pair of diodes 36, a p-channel MOSFET and an n-channel MOSFET 38, an NPN BJT and a PNP BJT 40, and/or a single BJT 42.

The second n-buried layer NBL2 24 includes a gate oxide situated on one or more of the second n-well region NW2 32 and the second p-well region PW2 34. The smaller second n-buried layer NBL2 24 that includes the gate oxide is referred to as the victim. The gate oxide in the second n-buried layer NBL2 24 can be one or more of the gates of a p-channel MOSFET and an n-channel MOSFET 44, with the gates connected to each other and to the junctions in the first n-buried layer NBL1 22 by the conductive path 26. The junctions in the first n-buried layer NBL1 22 are electrically connected to the gate oxide in the second n-buried layer NBL2 24 by the conductive path 26, such that charge can flow between the junctions in the first n-buried layer NBL1 22 and the gate oxide in the second n-buried layer NBL2 24 to cause well-PID.

As illustrated in FIG. 6, each of the n-channel MOSFETs in the first p-well region PW1 30 and in the second p-well region PW2 34 includes an N+ drain contact, an N+ source contact, a polysilicon gate contact with gate oxide, and a P+ well contact. Each of the p-channel MOSFETs in the first n-well region NW1 28 and in the second n-well region NW2 32 includes a P+ drain contact, a P+ source contact, a polysilicon gate contact with gate oxide, and an N+ well contact. In addition, each of the MOSFETs in the well-PID protection circuits 120, 122, 124, and 126 includes an N+ drain contact, an N+ source contact, a polysilicon gate contact with gate oxide, and a P+ substrate contact. In some embodiments, the P+ substrate contacts are grounded.

In reference to FIGS. 5 and 6, the well-PID protection circuit 120 includes a MOSFET 128 and a control circuit 130. The MOSFET 128 is an n-channel MOSFET and the control circuit 130 is configured to be connected to the gate of the MOSFET 128. In some embodiments, the MOSFET 128 is like the MOSFET 52 (shown in FIGS. 2 and 3) and, in some embodiments, the control circuit 130 is like the control circuit 54 (shown in FIGS. 2 and 3). In other embodiments, the MOSFET 128 is a p-channel MOSFET transistor.

The drain region D of the MOSFET 128 is connected to the first n-well region NW1 28 and the source region S of the MOSFET 128 is connected to a p-substrate 132. Also, the body of the MOSFET 128 is connected to the p-substrate 132. The well-PID protection circuit 120 is used to reduce or eliminate well-PID. In some embodiments, the p-substrate 132 is grounded.

The gate of the MOSFET 128 remains floating during the fabrication process, such that the MOSFET 128 is not biased completely off during the fabrication process. When voltage at the first n-well region NW1 28 is higher than voltage at the p-substrate 132, charge accumulated in the first n-well region NW1 28 is discharged through the reverse biased parasitic diode, like the parasitic diode 60 of the MOSFET 52, and through the extra leakage path, like the extra leakage path 62 of the MOSFET 52, from the drain to the source of the MOSFET 128. The gate remains floating during the fabrication process to create this extra leakage path and discharge charge that accumulates in the first n-well region NW1 28.

The gate of the MOSFET 128 is connected to the control circuit 130 at the end of the fabrication process or after the fabrication process. The MOSFET 128 is biased off by the control circuit 130 during operation of the integrated circuit.

The well-PID protection circuit 122 includes a MOSFET 134 and a control circuit 136. The MOSFET 134 is an n-channel MOSFET and the control circuit 136 is configured to be connected to the gate of the MOSFET 134. In some embodiments, the MOSFET 134 is like the MOSFET 52 (shown in FIGS. 2 and 3) and, in some embodiments, the control circuit 136 is like the control circuit 54 (shown in FIGS. 2 and 3). In other embodiments, the MOSFET 134 is a p-channel MOSFET transistor.

The drain region D of the MOSFET 134 is connected to the first p-well region PW1 30 and the source region S of the MOSFET 134 is connected to the p-substrate 132. Also, the body of the MOSFET 134 is connected to the p-substrate 132. The well-PID protection circuit 122 is used to reduce or eliminate well-PID. In some embodiments, the p-substrate 132 is grounded.

The gate of the MOSFET 134 remains floating during the fabrication process, such that the MOSFET 134 is not biased completely off during the fabrication process. When voltage at the first p-well region PW1 30 is higher than voltage at the p-substrate 132, charge accumulated in the first p-well region PW1 30 is discharged through the reverse biased parasitic diode, like the parasitic diode 60 of the MOSFET 52, and through the extra leakage path, like the extra leakage path 62 of the MOSFET 52, from the drain to the source of the MOSFET 134. The gate remains floating during the fabrication process to create this extra leakage path and discharge charge that accumulates in the first p-well region PW1 30.

The gate of the MOSFET 134 is connected to the control circuit 136 at the end of the fabrication process or after the fabrication process. The MOSFET 134 is biased off by the control circuit 136 during operation of the integrated circuit.

The well-PID protection circuit 124 includes a MOSFET 138 and a control circuit 140. The MOSFET 138 is an n-channel MOSFET and the control circuit 140 is configured to be connected to the gate of the MOSFET 138. In some embodiments, the MOSFET 138 is like the MOSFET 52 (shown in FIGS. 2 and 3) and, in some embodiments, the control circuit 140 is like the control circuit 54 (shown in FIGS. 2 and 3). In other embodiments, the MOSFET 138 is a p-channel MOSFET transistor.

The drain region D of the MOSFET 138 is connected to the second n-well region NW2 32 and the source region S of the MOSFET 138 is connected to the p-substrate 132. Also, the body of the MOSFET 138 is connected to the p-substrate 132. The well-PID protection circuit 124 is used to reduce or eliminate well-PID. In some embodiments, the p-substrate 132 is grounded.

The gate of the MOSFET 138 remains floating during the fabrication process, such that the MOSFET 138 is not biased completely off during the fabrication process. When voltage at the second n-well region NW2 32 is higher than voltage at the p-substrate 132, charge accumulated in the second n-well region NW2 32 is discharged through the reverse biased parasitic diode, like the parasitic diode 60 of the MOSFET 52, and through the extra leakage path, like the extra leakage path 62 of the MOSFET 52, from the drain to the source of the MOSFET 138. The gate remains floating during the fabrication process to create this extra leakage path and discharge charge that accumulates in the second n-well region NW2 32.

The gate of the MOSFET 138 is connected to the control circuit 140 at the end of the fabrication process or after the fabrication process. The MOSFET 138 is biased off by the control circuit 140 during operation of the integrated circuit.

The well-PID protection circuit 126 includes a MOSFET 142 and a control circuit 144. The MOSFET 142 is an n-channel MOSFET and the control circuit 144 is configured to be connected to the gate of the MOSFET 142. In some embodiments, the MOSFET 142 is like the MOSFET 52 (shown in FIGS. 2 and 3) and, in some embodiments, the control circuit 144 is like the control circuit 54 (shown in FIGS. 2 and 3). In other embodiments, the MOSFET 142 is a p-channel MOSFET transistor.

The drain region D of the MOSFET 142 is connected to the second p-well region PW2 34 and the source region S of the MOSFET 142 is connected to the p-substrate 132. Also, the body of the MOSFET 142 is connected to the p-substrate 132. The well-PID protection circuit 126 is used to reduce or eliminate well-PID. In some embodiments, the p-substrate 132 is grounded.

The gate of the MOSFET 142 remains floating during the fabrication process, such that the MOSFET 142 is not biased completely off during the fabrication process. When voltage at the second p-well region PW2 34 is higher than voltage at the p-substrate 132, charge accumulated in the second p-well region PW2 34 is discharged through the reverse biased parasitic diode, like the parasitic diode 60 of the MOSFET 52, and through the extra leakage path, like the extra leakage path 62 of the MOSFET 52, from the drain to the source of the MOSFET 142. The gate remains floating during the fabrication process to create this extra leakage path and discharge charge that accumulates in the second p-well region PW2 34.

The gate of the MOSFET 142 is connected to the control circuit 144 at the end of the fabrication process or after the fabrication process. The MOSFET 142 is biased off by the control circuit 144 during operation of the integrated circuit.

In fabrication of the semiconductor device 20, the metal connections for electrically connecting the well-PID protection circuits 120, 122, 124, and 126 to the first n-buried layer NBL1 22 and to the second n-buried layer NBL2 24 are formed prior to electrically connecting the first n-buried layer NBL1 22 to the second n-buried layer NBL2 24 by the conductive path 26, such that the charge accumulated in the n-wells and the p-wells is discharged through the well-PID protection circuits 120, 122, 124, and 126 before the first n-buried layer NBL1 22 and the second n-buried layer NBL2 24 are electrically connected by the conductive path 26. Thus, damage to the gate oxide in the second n-buried layer NBL2 24 is reduced and/or prevented. Also, the metal connections for electrically connecting the gates of the MOSFETs in the well-PID protection circuits 120, 122, 124, and 126 to control circuits are formed after the first n-buried layer NBL1 22 is electrically connected to the second n-buried layer NBL2 24 by the conductive path 26.

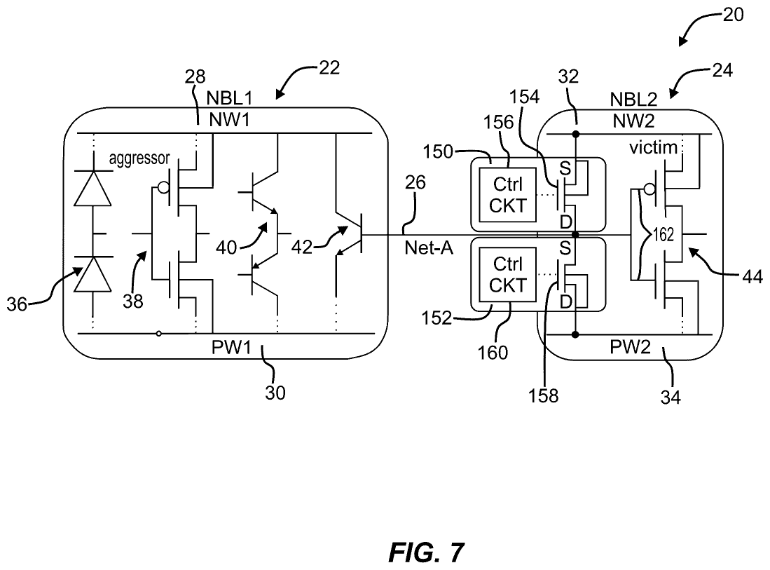

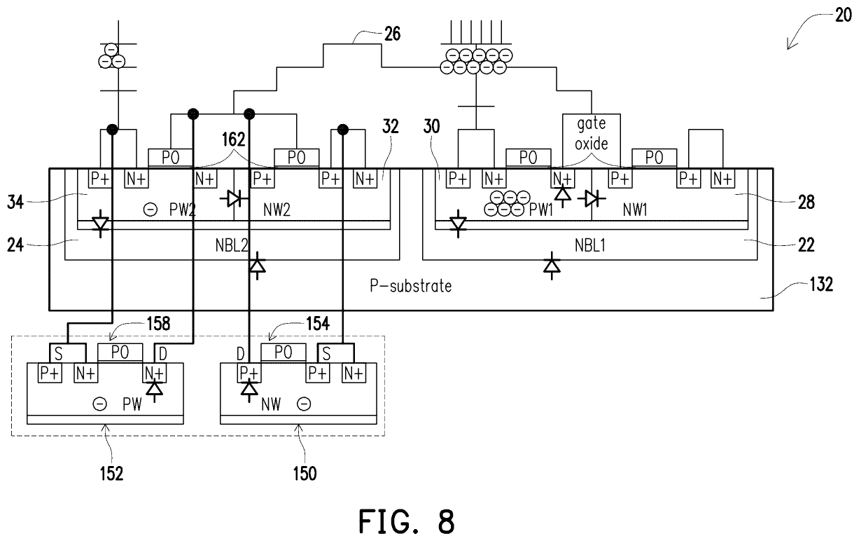

FIGS. 7 and 8 are diagrams schematically illustrating the semiconductor device 20 of FIG. 1 including local well-PID protection circuits 150 and 152, in accordance with some embodiments. The local well-PID protection circuits 150 and 152 are third option 3 well-PID protection (shown in FIG. 1). Each of the local well-PID protection circuits 150 and 152 is like the well-PID protection circuit 50 of FIGS. 2 and 3.

The local well-PID protection circuits 150 and 152 provide well-PID protection from the gate oxide 162 to the second n-well region NW2 32 and from the gate oxide 162 to the second p-well region PW2 34. Each of the local well-PID protection circuits 150 and 152 includes a MOSFET and a control circuit. In various embodiments, the MOSFET can be an NMOS transistor or a PMOS transistor based on the voltage applications of the local well-PID protection circuits 150 and 152, such as the voltage applications described in relation to well-PID protection circuits 70, 72, 74, and 76 of FIG. 4.

FIG. 7 is a diagram schematically illustrating the semiconductor device 20 including the local well-PID protection circuits 150 and 152 as third option 3 well-PID protection, in accordance with some embodiments. FIG. 8 is a cross-section diagram of the semiconductor device 20 of FIG. 7, in accordance with some embodiments.

In reference to FIGS. 7 and 8, the semiconductor device 20 includes the first n-buried layer NBL1 22 and the second n-buried layer NBL2 24. The first n-buried layer NBL1 22 is electrically connected to the second n-buried layer NBL2 24 by the conductive path 26. The first n-buried layer NBL1 22 includes the first n-well region NW1 28 and the first p-well region PW1 30, and the second n-buried layer NBL2 24 includes the second n-well region NW2 32 and the second p-well region PW2 34. Each of the first n-well region NW1 28 and the first p-well region PW1 30 is larger than each of the second n-well region NW2 32 and the second p-well region PW2 34.

The first n-buried layer NBL1 22 includes one or more junctions in the first n-well region NW1 28 and the first p-well region PW1 30. The larger first n-buried layer NBL1 22 with the junctions is referred to as the aggressor. The junctions can be in any suitable device such as a pair of diodes 36, a p-channel MOSFET and an n-channel MOSFET 38, an NPN BJT and a PNP BJT 40, and/or a single BJT 42.

The second n-buried layer NBL2 24 includes a gate oxide 162 situated on one or more of the second n-well region NW2 32 and the second p-well region PW2 34. The smaller second n-buried layer NBL2 24 that includes the gate oxide 162 is referred to as the victim. The gate oxide in the second n-buried layer NBL2 24 can be one or more of the gates of a p-channel MOSFET and an n-channel MOSFET 44, with the gates connected to each other and to the junctions in the first n-buried layer NBL1 22 by the conductive path 26. The junctions in the first n-buried layer NBL1 22 are electrically connected to the gate oxide 162 in the second n-buried layer NBL2 24 by the conductive path 26, such that charge can flow between the junctions in the first n-buried layer NBL1 22 and the gate oxide 162 in the second n-buried layer NBL2 24 to cause well-PID.

As illustrated in FIG. 8, each of the n-channel MOSFETs in the first p-well region PW1 30 and in the second p-well region PW2 34 includes an N+ drain contact, an N+source contact, a polysilicon gate contact (PO) with gate oxide, and a P+ well contact. Each of the p-channel MOSFETs in the first n-well region NW1 28 and in the second n-well region NW2 32 includes a P+ drain contact, a P+ source contact, a polysilicon gate contact (PO) with gate oxide, and an N+ well contact. In addition, the p-channel MOSFET in the local well-PID protection circuit 150 includes a P+ drain contact, a P+ source contact, a polysilicon gate contact (PO) with gate oxide, and an N+ substrate contact. The n-channel MOSFET in the local well-PID protection circuit 152 includes an N+ drain contact, an N+ source contact, a polysilicon gate contact (PO) with gate oxide, and a P+ substrate contact.

In reference to FIGS. 7 and 8, the local well-PID protection circuit 150 includes a MOSFET 154 and a control circuit 156. The MOSFET 154 is a p-channel MOSFET and the control circuit 156 is configured to be connected to the gate of the MOSFET 154. In some embodiments, the MOSFET 154 is like the MOSFET 52 (shown in FIGS. 2 and 3) and, in some embodiments, the control circuit 156 is like the control circuit 54 (shown in FIGS. 2 and 3). In other embodiments, the MOSFET 154 is an n-channel MOSFET transistor.

The source region S of the MOSFET 154 is connected to the second n-well region NW2 32 and the drain region D of the MOSFET 154 is connected to the conductive path 26. Also, the body of the MOSFET 154 is connected to the second n-well region NW2 32. The local well-PID protection circuit 150 is used to reduce or eliminate well-PID.

The gate of the MOSFET 154 remains floating during the fabrication process, such that the MOSFET 154 is not biased completely off during the fabrication process. When voltage at the gate oxide 162 (conductive path 26) is higher than voltage at the second n-well region NW2 32, charge accumulated at the gate oxide 162 is discharged through the reverse biased parasitic diode, like the parasitic diode 60 of the MOSFET 52, and through the extra leakage path, like the extra leakage path 62 of the MOSFET 52, from the drain to the source of the MOSFET 154. The gate remains floating during the fabrication process to create this extra leakage path and discharge charge that accumulates at the gate oxide.

The gate of the MOSFET 154 is connected to the control circuit 156 at the end of the fabrication process or after the fabrication process. The MOSFET 154 is biased off by the control circuit 156 during operation of the integrated circuit.

The local well-PID protection circuit 152 includes a MOSFET 158 and a control circuit 160. The MOSFET 158 is an n-channel MOSFET and the control circuit 160 is configured to be connected to the gate of the MOSFET 158. In some embodiments, the MOSFET 158 is like the MOSFET 52 (shown in FIGS. 2 and 3) and, in some embodiments, the control circuit 160 is like the control circuit 54 (shown in FIGS. 2 and 3). In other embodiments, the MOSFET 158 is a p-channel MOSFET transistor.

The drain region D of the MOSFET 158 is connected to the gate oxide 162 (conductive path 26) and the source region S of the MOSFET 158 is connected to the second p-well region PW2 34. Also, the body of the MOSFET 158 is connected to the second p-well region PW2 34. The local well-PID protection circuit 152 is used to reduce or eliminate well-PID.

The gate of the MOSFET 158 remains floating during the fabrication process, such that the MOSFET 158 is not biased completely off during the fabrication process. When voltage at the gate oxide 162 is higher than voltage at the second p-well region PW2 34, charge accumulated at the gate oxide is discharged through the reverse biased parasitic diode, like the parasitic diode 60 of the MOSFET 52, and through the extra leakage path, like the extra leakage path 62 of the MOSFET 52, from the drain to the source of the MOSFET 158. The gate remains floating during the fabrication process to create this extra leakage path and discharge charge that accumulates at the gate oxide.

The gate of the MOSFET 158 is connected to the control circuit 160 at the end of the fabrication process or after the fabrication process. The MOSFET 158 is biased off by the control circuit 160 during operation of the integrated circuit.

In fabrication of the semiconductor device 20, the metal connections for electrically connecting the local well-PID protection circuits 150 and 152 to the gate oxide 162 and to the second n-well region NW2 32 and the second p-well region PW2 34 are formed prior to electrically connecting the first n-buried layer NBL1 22 to the second n-buried layer NBL2 24 by the conductive path 26, such that the charge accumulated at the gate oxide 162 (and in the n-wells and the p-wells) is discharged through the local well-PID protection circuits 150 and 152 before the first n-buried layer NBL1 22 and the second n-buried layer NBL2 24 are electrically connected by the conductive path 26. Thus, damage to the gate oxide 162 in the second n-buried layer NBL2 24 is reduced and/or prevented. Also, the metal connections for electrically connecting the gates of the MOSFETs in the local well-PID protection circuits 150 and 152 to control circuits are formed after the first n-buried layer NBL1 22 is electrically connected to the second n-buried layer NBL2 24 by the conductive path 26.

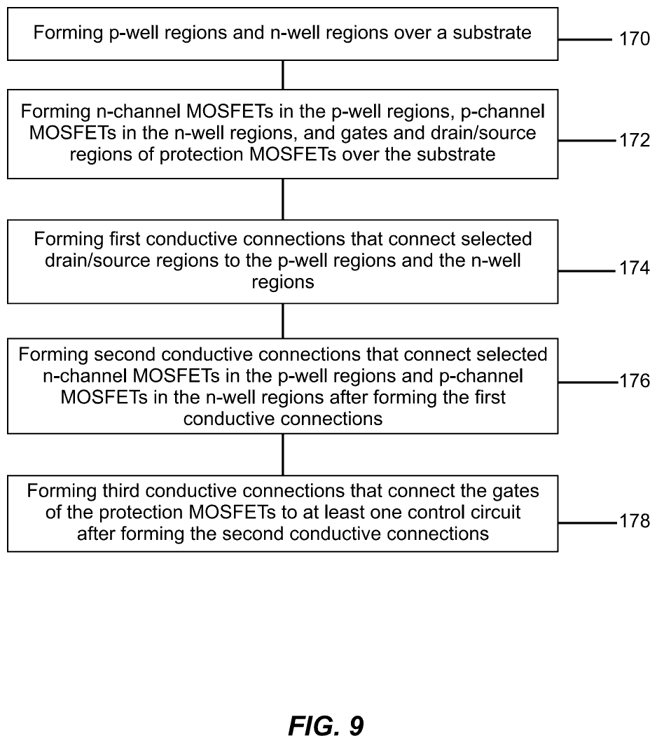

FIG. 9 is a method of fabricating a semiconductor device, in accordance with some embodiments. At 170, the method includes forming p-well regions and n-well regions over a substrate.

At 172, the method includes forming n-channel MOSFETs in the p-well regions, p-channel MOSFETs in the n-well regions, and gates and drain/source regions of protection MOSFETs over the substrate. In some embodiments, forming the n-channel MOSFETs in the p-well regions, p-channel MOSFETs in the n-well regions, and gates and drain/source regions of protection MOSFETs includes forming the n-channel MOSFETs in the p-well regions, the p-channel MOSFETs in the n-well regions, and the gates and drain/source regions of protection MOSFETs simultaneously. In some embodiments, forming n-channel MOSFETs in the p-well regions, p-channel MOSFETs in the n-well regions, and gates and drain/source regions of protection MOSFETs further includes forming bipolar junction transistors over the substrate.

At 174, the method includes forming first conductive connections that connect selected drain/source regions to the p-well regions and the n-well regions.

At 176, the method includes forming second conductive connections that connect selected n-channel MOSFETs in the p-well regions and p-channel MOSFETs in the n-well regions after forming the first conductive connections.

At 178, the method includes forming third conductive connections that connect the gates of the protection MOSFETs to at least one control circuit after forming the second conductive connections. In some embodiments, forming the third conductive connections includes forming a third conductive connection from each of the gates of the protection MOSFETs to a different one of the at least one control circuit.

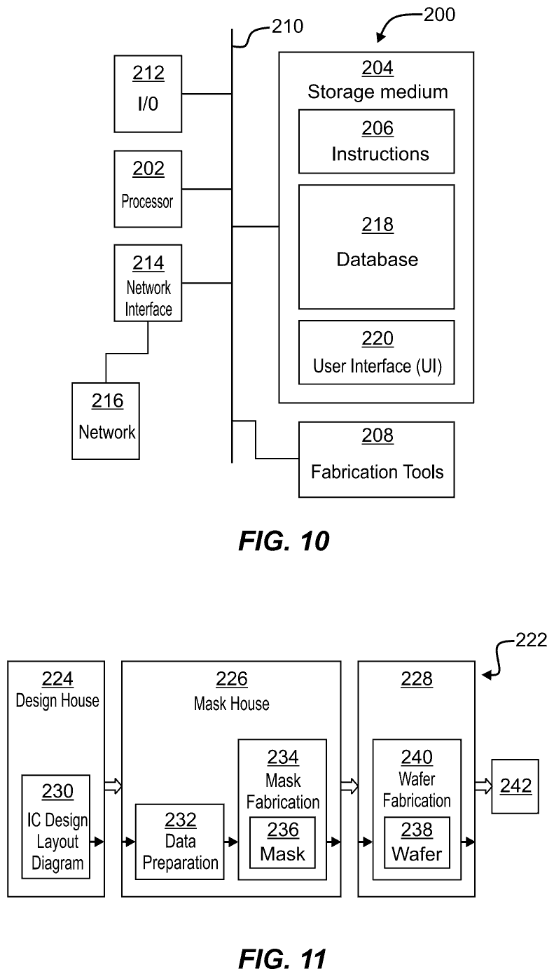

FIG. 10 is a block diagram schematically illustrating an example of a computer system 200 configured to provide the semiconductor devices and methods of the current disclosure, in accordance with some embodiments. Some or all the design, layout, and manufacture of the semiconductor devices, also referred to as semiconductor circuits, can be performed by or with the computer system 200. In some embodiments, the computer system 200 includes an electronic design automation (EDA) system. In some embodiments, the semiconductor devices are ICs.

In some embodiments, the system 200 is a general-purpose computing device including a processor 202 and a non-transitory, computer-readable storage medium 204. The computer-readable storage medium 204 may be encoded with, e.g., store, computer program code such as executable instructions 206. Execution of the instructions 206 by the processor 202 provides (at least in part) a design tool that implements a portion or all the functions of the system 200, such as pre-layout simulations, post-layout simulations, routing, rerouting, and final layout for manufacturing. Further, fabrication tools 208 are included to further layout and physically implement the design and manufacture of the semiconductor devices. In some embodiments, execution of the instructions 206 by the processor 202 provides (at least in part) a design tool that implements a portion or all the functions of the system 200. In some embodiments, the system 200 includes a commercial router. In some embodiments, the system 200 includes an automatic place and route (APR) system.

The processor 202 is electrically coupled to the computer-readable storage medium 204 by a bus 210 and to an I/O interface 212 by the bus 210. A network interface 214 is also electrically connected to the processor 202 by the bus 210. The network interface 214 is connected to a network 216, so that the processor 202 and the computer-readable storage medium 204 can connect to external elements using the network 216. The processor 202 is configured to execute the computer program code or instructions 206 encoded in the computer-readable storage medium 204 to cause the system 200 to perform a portion or all the functions of the system 200, such as providing the semiconductor devices and methods of the current disclosure and other functions of the system 200. In some embodiments, the processor 202 is a central processing unit (CPU), a multi-processor, a distributed processing system, an application specific integrated circuit (ASIC), and/or a suitable processing unit.

In some embodiments, the computer-readable storage medium 204 is an electronic, magnetic, optical, electromagnetic, infrared, and/or semiconductor system or apparatus or device. For example, the computer-readable storage medium 204 can include a semiconductor or solid-state memory, a magnetic tape, a removable computer diskette, a random-access memory (RAM), a read-only memory (ROM), a rigid magnetic disk, and/or an optical disk. In some embodiments using optical disks, the computer-readable storage medium 204 can include a compact disk read only memory (CD-ROM), a compact disk read/write memory (CD-R/W), and/or a digital video disc (DVD).

In some embodiments, the computer-readable storage medium 204 stores computer program code or instructions 206 configured to cause the system 200 to perform a portion or all the functions of the system 200. In some embodiments, the computer-readable storage medium 204 also stores information which facilitates performing a portion or all the functions of the system 200. In some embodiments, the computer-readable storage medium 204 stores a database 218 that includes one or more of component libraries, digital circuit cell libraries, and databases.

The system 200 includes the I/O interface 212, which is coupled to external circuitry. In some embodiments, the I/O interface 212 includes a keyboard, keypad, mouse, trackball, trackpad, touchscreen, and/or cursor direction keys for communicating information and commands to the processor 202.

The network interface 214 is coupled to the processor 202 and allows the system 200 to communicate with the network 216, to which one or more other computer systems are connected. The network interface 214 can include: wireless network interfaces such as BLUETOOTH, WIFI, WIMAX, GPRS, or WCDMA; or wired network interfaces such as ETHERNET, USB, or IEEE-1364. In some embodiments, a portion or all the functions of the system 200 can be performed in two or more systems that are like system 200.

The system 200 is configured to receive information through the I/O interface 212. The information received through the I/O interface 212 includes one or more of instructions, data, design rules, libraries of components and cells, and/or other parameters for processing by the processor 202. The information is transferred to the processor 202 by the bus 210. Also, the system 200 is configured to receive information related to a user interface (UI) through the I/O interface 212. This UI information can be stored in the computer-readable storage medium 204 as a UI 220.

In some embodiments, a portion or all the functions of the system 200 are implemented via a standalone software application for execution by a processor. In some embodiments, a portion or all the functions of the system 200 are implemented in a software application that is a part of an additional software application. In some embodiments, a portion or all the functions of the system 200 are implemented as a plug-in to a software application. In some embodiments, at least one of the functions of the system 200 is implemented as a software application that is a portion of an EDA tool. In some embodiments, a portion or all the functions of the system 200 are implemented as a software application that is used by the system 200. In some embodiments, a layout diagram is generated using a tool such as VIRTUOSO available from CADENCE DESIGN SYSTEMS, Inc., or another suitable layout generating tool.

In some embodiments, the routing, layouts, and other processes are realized as functions of a program stored in a non-transitory computer readable recording medium. Examples of a non-transitory computer readable recording medium include, but are not limited to, external/removable and/or internal/built-in storage or memory units, e.g., one or more optical disks such as a digital video disc or a digital versatile disc (DVD), a magnetic disk such as a hard disk, a semiconductor memory such as a ROM and a RAM, and a memory card, and the like.

As noted above, embodiments of the system 200 include fabrication tools 208 for implementing the manufacturing processes of the system 200. For example, based on the final layout, photolithographic masks may be generated, which are used to fabricate the semiconductor device by the fabrication tools 208.

Further aspects of device fabrication are disclosed in conjunction with FIG. 11, which is a block diagram of a semiconductor device manufacturing system 222 and a semiconductor device manufacturing flow associated therewith, in accordance with some embodiments. In some embodiments, based on a layout diagram, one or more semiconductor masks and/or at least one component in a layer of a semiconductor device is fabricated using the manufacturing system 222.

In FIG. 11, the semiconductor device manufacturing system 222 includes entities, such as a design house 224, a mask house 226, and a semiconductor device manufacturer/fabricator (“Fab”) 228, that interact with one another in the design, development, and manufacturing cycles and/or services related to manufacturing a semiconductor device, such as the semiconductor devices described herein. The entities in the system 222 are connected by a communications network. In some embodiments, the communications network is a single network. In some embodiments, the communications network is a variety of different networks, such as an intranet and the internet. The communications network includes wired and/or wireless communication channels. Each entity interacts with one or more of the other entities and provides services to and/or receives services from one or more of the other entities. In some embodiments, two or more of the design house 224, the mask house 226, and the semiconductor device fab 228 are owned by a single larger company. In some embodiments, two or more of the design house 224, the mask house 226, and the semiconductor device fab 228 coexist in a common facility and use common resources.

The design house (or design team) 224 generates a semiconductor device design layout diagram 230. The semiconductor device design layout diagram 230 includes various geometrical patterns, or semiconductor device layout diagrams designed for a semiconductor device. The geometrical patterns correspond to patterns of metal, oxide, or semiconductor layers that make up the various components of the semiconductor structures to be fabricated. The various layers combine to form various semiconductor device features. For example, a portion of the semiconductor device design layout diagram 230 includes various semiconductor device features, such as diagonal vias, active areas or regions, gate electrodes, sources, drains, metal lines, local vias, and openings for bond pads, to be formed in a semiconductor substrate (such as a silicon wafer) and in various material layers disposed on the semiconductor substrate. The design house 224 implements a design procedure to form a semiconductor device design layout diagram 230. The semiconductor device design layout diagram 230 is presented in one or more data files having information of the geometrical patterns. For example, semiconductor device design layout diagram 230 can be expressed in a GDSII file format or DFII file format. In some embodiments, the design procedure includes one or more of analog circuit design, digital circuit design, logic circuit design, standard cell circuit design, power distribution network (PDN) design including power via design, supply voltage track design, reference voltage track design, place and route routines, and physical layout designs.

The mask house 226 includes data preparation 232 and mask fabrication 234. The mask house 226 uses the semiconductor device design layout diagram 230 to manufacture one or more masks 236 to be used for fabricating the various layers of the semiconductor device or semiconductor structure. The mask house 226 performs mask data preparation 232, where the semiconductor device design layout diagram 230 is translated into a representative data file (RDF). The mask data preparation 232 provides the RDF to the mask fabrication 234. The mask fabrication 234 includes a mask writer that converts the RDF to an image on a substrate, such as a mask (reticle) 236 or a semiconductor wafer 238. The design layout diagram 230 is manipulated by the mask data preparation 232 to comply with characteristics of the mask writer and/or criteria of the semiconductor device fab 228. In FIG. 11, the mask data preparation 232 and the mask fabrication 234 are illustrated as separate elements. In some embodiments, the mask data preparation 232 and the mask fabrication 234 can be collectively referred to as mask data preparation.

In some embodiments, the mask data preparation 232 includes an optical proximity correction (OPC) which uses lithography enhancement techniques to compensate for image errors, such as those that can arise from diffraction, interference, other process effects and the like. The OPC adjusts the semiconductor device design layout diagram 230. In some embodiments, the mask data preparation 232 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 232 includes a mask rule checker (MRC) that checks the semiconductor device design layout diagram 230 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the semiconductor device design layout diagram 230 to compensate for limitations during the mask fabrication 234, which may undo part of the modifications performed by OPC to meet mask creation rules.

In some embodiments, the mask data preparation 232 includes lithography process checking (LPC) that simulates processing that will be implemented by the semiconductor device fab 228. LPC simulates this processing based on the semiconductor device design layout diagram 230 to create a simulated manufactured device. The processing parameters in LPC simulation can include parameters associated with various processes of the semiconductor device manufacturing cycle, parameters associated with tools used for manufacturing the semiconductor device, and/or other aspects of the manufacturing process. LPC considers various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine the semiconductor device design layout diagram 230.

The above description of mask data preparation 232 has been simplified for the purposes of clarity. In some embodiments, data preparation 232 includes additional features such as a logic operation (LOP) to modify the semiconductor device design layout diagram 230 according to manufacturing rules. Additionally, the processes applied to the semiconductor device design layout diagram 230 during data preparation 232 may be executed in a variety of different orders.

After the mask data preparation 232 and during the mask fabrication 234, a mask 236 or a group of masks 236 are fabricated based on the modified semiconductor device design layout diagram 230. In some embodiments, the mask fabrication 234 includes performing one or more lithographic exposures based on the semiconductor device design layout diagram 230. In some embodiments, an electron-beam (e-beam) or a mechanism of multiple e-beams is used to form a pattern on a mask (photomask or reticle) 236 based on the modified semiconductor device design layout diagram 230. The mask 236 can be formed in various technologies. In some embodiments, the mask 236 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region, and transmits through the transparent regions. In one example, a binary mask version of the mask 236 includes a transparent substrate (e.g., fused quartz) and an opaque material (e.g., chromium) coated in the opaque regions of the binary mask. In another example, the mask 236 is formed using a phase shift technology. In a phase shift mask (PSM) version of the mask 236, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 234 is used in a variety of processes. For example, such a mask(s) is used in an ion implantation process to form various doped regions in the semiconductor wafer 238, in an etching process to form various etching regions in the semiconductor wafer 238, and/or in other suitable processes.

The semiconductor device fab 228 includes wafer fabrication 240. The semiconductor device fab 228 is a semiconductor device fabrication business that includes one or more manufacturing facilities for the fabrication of a variety of different semiconductor device products. In some embodiments, the semiconductor device fab 228 is a semiconductor foundry. For example, there may be a manufacturing facility for the front end of line (FEOL) fabrication of a plurality of semiconductor device products, while a second manufacturing facility may provide the back end of line (BEOL) fabrication for the interconnection and packaging of the semiconductor device products, and a third manufacturing facility may provide other services for the foundry business.

The semiconductor device fab 228 uses the mask(s) 236 fabricated by the mask house 226 to fabricate the semiconductor structures or semiconductor devices 242 of the current disclosure. Thus, the semiconductor device fab 228 at least indirectly uses the semiconductor device design layout diagram 230 to fabricate the semiconductor structures or semiconductor devices 242 of the current disclosure. Also, the semiconductor wafer 238 includes a silicon substrate or other proper substrate having material layers formed thereon, and the semiconductor wafer 238 further includes one or more of various doped regions, dielectric features, multilevel interconnects, and the like (formed at subsequent manufacturing steps). In some embodiments, the semiconductor wafer 238 is fabricated by the semiconductor device fab 228 using the mask(s) 236 to form the semiconductor structures or semiconductor devices 242 of the current disclosure. In some embodiments, the semiconductor device fabrication includes performing one or more lithographic exposures based at least indirectly on the semiconductor device design layout diagram 230.

Disclosed embodiments of the present application provide well-PID protection circuits and methods for protecting semiconductor devices from well-PID in MOSFETs. The well-PID may be related to one or more n-wells and/or to one or more p-wells in the semiconductor device.

Disclosed embodiments include well-PID protection circuits that include a control circuit and a MOSFET. The control circuit is configured to be connected to a gate of the MOSFET. The MOSFET includes drain/source regions that are connected to well regions, gate oxides, and substrates. During fabrication of the semiconductor device, the gate of the MOSFET floats such that charge accumulated in the well regions, the gate oxides, and/or the substrate discharges through the MOSFET. In operation of the semiconductor device, the control circuit is connected to the gate of the MOSFET to bias off the MOSFET and prevent current from flowing through the MOSFET.

Advantages and benefits of the disclosed embodiments include low or small impact on area, little or no impact on functionality, no ESD concerns, suitable for all designs including designs with different voltage applications, and suitable for every technology node including advanced finFET and planar processes.

In accordance with some embodiments, a circuit includes a substrate, p-well regions over the substrate and including n-channel MOSFETs, n-well regions over the substrate and including p-channel MOSFETs, drain/source regions of protection MOSFETs, and at least one control circuit. First conductive connections connect selected drain/source regions to the p-well regions and the n-well regions, second conductive connections connect selected n-channel MOSFETs and p-channel MOSFETs to one another, and third conductive connections are configured to connect gates of the protection MOSFETs to the at least one control circuit.

In accordance with further embodiments, a circuit includes a substrate, a first well region over the substrate, a second well region over the substrate, a first MOSFET in the first well region, and a second MOSFET in the second well region. A first control circuit is connected to a first gate of the first MOSFET and a second control circuit is connected to a second gate of the second MOSFET.

In accordance with still further disclosed aspects, a method includes forming p-well regions and n-well regions over a substrate; forming n-channel MOSFETs in the p-well regions, p-channel MOSFETs in the n-well regions, and gates and drain/source regions of protection MOSFETs over the substrate; forming first conductive connections that connect selected drain/source regions to the p-well regions and the n-well regions; forming second conductive connections that connect selected n-channel MOSFETs in the p-well regions and p-channel MOSFETs in the n-well regions after forming the first conductive connections; and forming third conductive connections that connect the gates of the protection MOSFETs to at least one control circuit after forming the second conductive connections.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit, comprising:
a substrate;
p-well regions over the substrate and including n-channel metal-oxide semiconductor field-effect transistors;
n-well regions over the substrate and including p-channel metal-oxide semiconductor field-effect transistors;
drain/source regions of protection metal-oxide semiconductor field-effect transistors;
at least one control circuit;
first conductive connections that connect selected drain/source regions to the p-well regions and the n-well regions;
second conductive connections that connect selected n-channel metal-oxide semiconductor field-effect transistors and p-channel metal-oxide semiconductor field-effect transistors to one another; and
third conductive connections configured to connect gates of the protection metal-oxide semiconductor field-effect transistors to the at least one control circuit.

2. The circuit of claim 1, wherein a first drain/source region of a first protection metal-oxide semiconductor field-effect transistor is connected to one of the p-well regions or to one of the n-well regions and a second drain/source region of the first protection metal-oxide semiconductor field-effect transistor is connected to the substrate.

3. The circuit of claim 1, wherein a first drain/source region of a first protection metal-oxide semiconductor field-effect transistor is connected to one of the p-well regions or to one of the n-well regions and a second drain/source region of the first metal-oxide semiconductor field-effect transistor is connected to one of the second conductive connections.

4. The circuit of claim 1, wherein a gate of one of the protection metal-oxide semiconductor field-effect transistors floats to discharge accumulated charge through the one of the protection metal-oxide semiconductor field-effect transistors and the at least one control circuit is connected to the gate to bias off the one of the protection metal-oxide semiconductor field-effect transistors during operation of the circuit.

5. The circuit of claim 4, wherein a first drain/source region of the one of the protection metal-oxide semiconductor field-effect transistors is connected to one of the p-well regions or to one of the n-well regions and a second drain/source region of the one of the protection metal-oxide semiconductor field-effect transistors is connected to the substrate.

6. The circuit of claim 4, wherein a first drain/source region of one of the protection metal-oxide semiconductor field-effect transistors is connected to one of the p-well regions or to one of the n-well regions and a second drain/source region of the one of the protection metal-oxide semiconductor field-effect transistors is connected to one of the second conductive connections.

7. The circuit of claim 1, wherein a first metal-oxide semiconductor field-effect transistor is an n-channel metal-oxide semiconductor field-effect transistor having a drain region connected to one of the p-well/n-well regions or the substrate, whichever has a higher voltage.

8. The circuit of claim 1, wherein a first metal-oxide semiconductor field-effect transistor is a p-channel metal-oxide semiconductor field-effect transistor having a source region connected to one of the p-well/n-well regions or the substrate, whichever has a higher voltage.

9. The circuit of claim 1, comprising at least one of a buried layer and a deep buried layer.

10. The circuit of claim 1, wherein the at least one control circuit includes one or more of an inverter, a NOR gate, and a NAND gate.

11. A circuit, comprising:
a substrate;
a first well region over the substrate;
a second well region over the substrate;
a first metal-oxide semiconductor field-effect transistor in the first well region;
a second metal-oxide semiconductor field-effect transistor in the second well region;
a first control circuit connected to a first gate of the first metal-oxide semiconductor field-effect transistor; and
a second control circuit connected to a second gate of the second metal-oxide semiconductor field-effect transistor.

12. The circuit of claim 11, wherein the first gate of the first metal-oxide semiconductor field-effect transistor floats to discharge accumulated charge through the first metal-oxide semiconductor field-effect transistor and the second gate of the second metal-oxide semiconductor field-effect transistor floats to discharge accumulated charge through the second metal-oxide semiconductor field-effect transistor.

13. The circuit of claim 11, wherein a first drain/source region of the first metal-oxide semiconductor field-effect transistor is connected to the first well region and a second drain/source region of the first metal-oxide semiconductor field-effect transistor is connected to the substrate.

14. The circuit of claim 13, wherein a first drain/source region of the second metal-oxide semiconductor field-effect transistor is connected to the second well region and a second drain/source region of the second metal-oxide semiconductor field-effect transistor is connected to the substrate.

15. The circuit of claim 11, comprising a connection between devices, wherein a first drain/source region of the first metal-oxide semiconductor field-effect transistor is connected to the first well region and a second drain/source region of the first metal-oxide semiconductor field-effect transistor is connected to the connection between devices.

16. The circuit of claim 15, wherein a first drain/source region of the second metal-oxide semiconductor field-effect transistor is connected to the second well region and a second drain/source region of the second metal-oxide semiconductor field-effect transistor is connected to the connection between devices.

17. A method, comprising:
forming p-well regions and n-well regions over a substrate;
forming n-channel metal-oxide semiconductor field-effect transistors in the p-well regions, p-channel metal-oxide semiconductor field-effect transistors in the n-well regions, and gates and drain/source regions of protection metal-oxide semiconductor field-effect transistors over the substrate;
forming first conductive connections that connect selected drain/source regions to the p-well regions and the n-well regions;
forming second conductive connections that connect selected n-channel metal-oxide semiconductor field-effect transistors in the p-well regions and p-channel metal-oxide semiconductor field-effect transistors in the n-well regions after forming the first conductive connections; and
forming third conductive connections that connect the gates of the protection metal-oxide semiconductor field-effect transistors to at least one control circuit after forming the second conductive connections.

18. The method of claim 17, wherein forming third conductive connections comprises forming a third conductive connection from each of the gates of the protection metal-oxide semiconductor field-effect transistors to a different one of the at least one control circuit after forming the second conductive connections.

19. The method of claim 17, wherein forming n-channel metal-oxide semiconductor field-effect transistors in the p-well regions, p-channel metal-oxide semiconductor field-effect transistors in the n-well regions, and gates and drain/source regions of protection metal-oxide semiconductor field-effect transistors further includes forming bipolar junction transistors over the substrate.

20. The method of claim 17, wherein forming n-channel metal-oxide semiconductor field-effect transistors in the p-well regions, p-channel metal-oxide semiconductor field-effect transistors in the n-well regions, and gates and drain/source regions of protection metal-oxide semiconductor field-effect transistors includes forming the n-channel metal-oxide semiconductor field-effect transistors in the p-well regions, the p-channel metal-oxide semiconductor field-effect transistors in the n-well regions, and the gates and drain/source regions of protection metal-oxide semiconductor field-effect transistors simultaneously.
